(19) United States
(12) Patent Application Publication
(10) Pub. No.: US 2026/0068350 A1
(43) Pub. Date: Mar. 5, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Jia LIU, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/056,823

(22) Filed: Feb. 19, 2025

(30) Foreign Application Priority Data
Aug. 30, 2024 (JP) 2024-149904

(51) Int. Cl. H10F 55/25; H01L 23/00; H01L 23/66; H01L 25/16

(52) U.S. Cl. CPC H10F 55/25

(57) ABSTRACT

According to one embodiment, a semiconductor device includes a first transistor and a second transistor whose source electrodes are electrically coupled to each other; a light emitter; a light receiver including a first cathode electrode and a second cathode electrode and configured to turn the first transistor and the second transistor on or off, depending on a light emission state of the light emitter; a first filter electrically coupling the first cathode electrode of the light receiver and the source electrode of the first transistor; and a second filter electrically coupling the second cathode electrode of the light receiver and the source electrode of the second transistor.

### CROSS-REFERENCE TO RELATED APPLICATIONS

This application is based upon and claims the benefit of priority from Japanese Patent Application No. 2024-149904, filed Aug. 30, 2024, the entire contents of which are incorporated herein by reference.

### FIELD

Embodiments described herein relate generally to a semiconductor device.

### BACKGROUND

A photorelay device including a light emitter and a light receiver is known as a semiconductor device. The photorelay device is a contactless relay and is used for transmitting AC signals and DC signals.

### BRIEF DESCRIPTION OF THE DRAWINGS

FIG. 1 is a circuit diagram showing an example of a circuit configuration of a semiconductor device according to a first embodiment.

FIG. 2 is a perspective view showing an example of a structure of the semiconductor device according to the first embodiment.

FIG. 3 is a plan view showing an example of a planar layout of the semiconductor device according to the first embodiment.

FIG. 4 is a circuit diagram showing an example of a circuit configuration of a semiconductor device according to a second embodiment.

FIG. 5 is a perspective view showing an example of a structure of the semiconductor device according to the second embodiment.

FIG. 6 is a plan view showing an example of a planar layout of the semiconductor device according to the second embodiment.

FIG. 7 is a plan view showing an example of a planar layout of a semiconductor device according to a first modification.

FIG. 8 is a plan view showing an example of a planar layout of a semiconductor device according to a second modification.

### DETAILED DESCRIPTION

In general, according to one embodiment, a semiconductor device includes a first transistor and a second transistor whose source electrodes are electrically coupled to each other; a light emitter; a light receiver including a first cathode electrode and a second cathode electrode and configured to turn the first transistor and the second transistor on or off, depending on a light emission state of the light emitter; a first filter electrically coupling the first cathode electrode of the light receiver and the source electrode of the first transistor; and a second filter electrically coupling the second cathode electrode of the light receiver and the source electrode of the second transistor.

A description will now be given of embodiments with reference to the accompanying drawings. In the descriptions below, components having similar functions and configurations will be denoted by the same reference symbols. It should be noted that the dimensions, scales etc. of the drawings are not necessarily the same as those of actual products.

A semiconductor device according to the embodiments is, for example, a photorelay device used for transmitting AC signals and DC signals. The semiconductor device according to the embodiments is, for example, an electronic component package. In the description below, both the AC signals and the DC signals may be simply referred to as signals.

### 1. First Embodiment

A semiconductor device according to the first embodiment will be described.

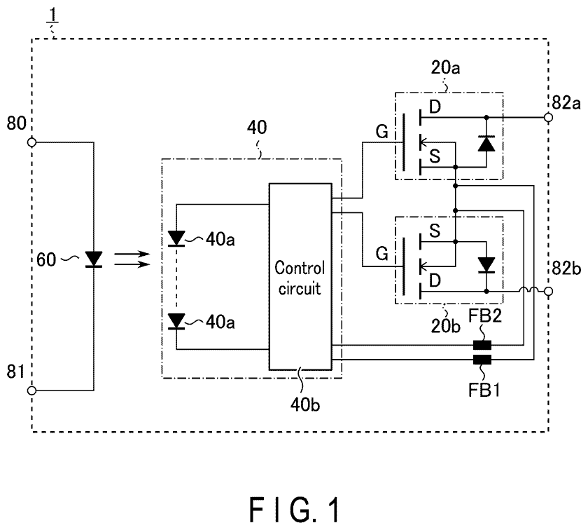

FIG. 1 is a circuit diagram showing an example of a circuit configuration of the semiconductor device according to the first embodiment.

The semiconductor device 1 includes electrodes 80, 81, 82a and 82b. The electrodes 80 and 81 are terminals provided on the outside of a package, and a voltage for driving the semiconductor device 1 is supplied to them from the outside. While the semiconductor device 1 is being driven, the semiconductor device 1 can transmit signals via the electrodes 82a and 82b.

The semiconductor device 1 further includes MOSFETS (metal-oxide-semiconductor field-effect transistors) 20a and 20b, a light receiver 40, a light emitter 60, and ferrite beads FB1 and FB2. The MOSFETs 20a and 20b are, for example, enhancement-type N-channel MOSFETs. The light receiver 40 is, for example, a sensor including a photo diode array (PDA) or a phototransistor. In the following, a description will be given of a case where the light receiver 40 includes a PDA. The light emitter 60 is, for example, an LED (light-emitting diode).

An anode electrode of the light emitter 60 is coupled to the electrode 80. A cathode electrode of the light emitter 60 is coupled to the electrode 81. The light emitter 60 is driven by power supplied to the electrodes 80 and 81. This causes the emission state of the light emitter 60 to switch to either an on state (lit state) or an off state (unlit state).

The light receiver 40 includes, for example, a plurality of photodiodes 40a coupled in series and a control circuit 40b. The number of photodiodes 40a is, for example, several to several tens. Both ends of the plurality of photodiodes 40a coupled in series are coupled to the control circuit 40b. The control circuit 40b uses the photovoltaic power generated by the plurality of photodiodes 40a to turn on the MOSFETs 20a and 20b.

A gate of the MOSFET 20a is coupled to a first anode electrode of the light receiver 40. A gate of the MOSFET 20b is coupled to a second anode electrode of the light receiver 40. A source of the MOSFET 20a is coupled to a first cathode electrode of the light receiver 40 via the ferrite bead FB1. A source of the MOSFET 20b is coupled to a second cathode electrode of the light receiver 40 via the ferrite bead FB2. A drain of the MOSFET 20a is coupled to the electrode 82a. A drain of the MOSFET 20b is coupled to the electrode 82b.

The first and second anode electrodes of the light receiver 40 are configured to have the same potential, for example, by being electrically coupled within the light receiver 40. The first and second cathode electrodes of the light receiver 40 are configured to have the same potential, for example, by being electrically coupled within the light receiver 40.

In the circuit configuration of the semiconductor device 1 described above, the light emitter 60 emits light when it switches from the off state to the on state. The light receiver 40 uses a voltage generated by the photovoltaic effect caused by the light of the light emitter 60 to switch the MOSFETs 20a and 20b from the off state to the on state. Thus, the electrodes 82a and 82b are electrically coupled to each other. In this manner, the semiconductor device 1 transmits a signal supplied to either the electrode 82a or 82b to the other electrode via the MOSFETs 20a and 20b.

When the light emitter 60 switches from the on state to the off state, the emission of light from the light emitter 60 stops. Thus, the MOSFETs 20a and 20b switch from the on state to the off state. In this manner, the semiconductor device 1 electrically insulates the electrodes 82a and 82b.

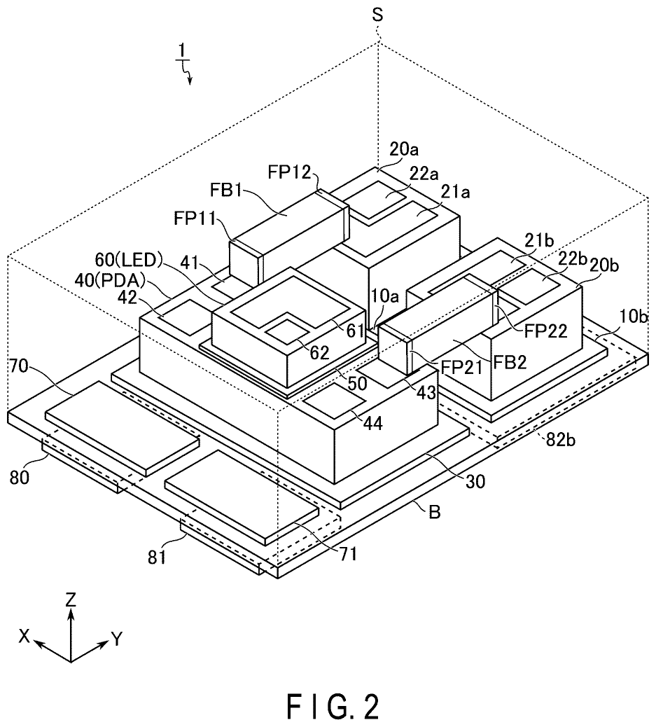

Next, the structure of the semiconductor device 1 will be described with reference to FIG. 2. FIG. 2 is a perspective view showing an example of a structure of the semiconductor device according to the first embodiment.

In the description below, the Z direction corresponds to the direction perpendicular to a surface of a substrate on which the semiconductor device 1 is formed. The X direction corresponds to a short side direction on the surface of the substrate. The Y direction corresponds to a long side direction on the surface of the substrate and is, for example, perpendicular to the X direction. It should be noted that in FIG. 2, illustration of the wiring is omitted to make the drawing easy to understand. The wiring will be described later.

The semiconductor device 1 further includes a substrate B, electrode pads 10a, 10b, 70 and 71, a support base 30, an adhesive layer 50, and a sealing material S. In the description below, a side of the substrate B on which the MOSFET 20a is provided will be referred to as an upper side. A side of the substrate B which is opposite the MOSFET 20a will be referred to as a lower side.

The substrate B is, for example, a circuit board using BT (bismaleimide triazine) resin, or a flexible substrate (FPC: flexible printed circuit) using polyimide.

The electrode pads 10a, 10b, 70 and 71 are electrode pads for mounting components to be provided on the upper face of the substrate B and are electrically coupled to the electrodes 82a, 82b, 80 and 81, which are external electrodes, respectively. The electrode pads 10a, 10b, 70 and 71 are, for example, metal foils containing copper. The electrode pads 10a and 70 are arranged apart from each other in the Y direction. The electrode pads 10b and 71 are arranged apart from each other in the Y direction. Furthermore, the electrode pads 10a and 10b are arranged apart from each other in the X direction. The electrode pads 70 and 71 are arranged apart from each other in the X direction.

The MOSFET 20a includes electrodes 21a and 22a, and an electrode (not shown in FIG. 2) arranged on a lower portion of the MOSFET 20a. The electrodes 21a and 22a are arranged on an upper face of the MOSFET 20a. The electrode arranged on the lower portion of the MOSFET 20a is in contact with the electrode pad 10a, for example, via a conductive paste or the like. For example, the electrode arranged on the lower portion of the MOSFET 20a may have a size equivalent to that of the lower face of the MOSFET 20a. The electrode 21a functions as a source electrode of the MOSFET 20a. The electrode 22a functions as a gate electrode of the MOSFET 20a. The electrode arranged on the lower portion of the MOSFET 20a functions as a drain electrode of the MOSFET 20a.

The MOSFET 20b includes electrodes 21b and 22b, and an electrode (not shown in FIG. 2) arranged on a lower portion of MOSFET 20b. The electrodes 21b and 22b are arranged on an upper face of the MOSFET 20b. The electrode arranged on the lower portion of the MOSFET 20b is in contact with the electrode pad 10b via a conductive paste or the like. For example, the electrode arranged on the lower portion of the MOSFET 20b may have a size equivalent to that of the lower face of the MOSFET 20b. The electrode 21b functions as a source electrode of the MOSFET 20b. The electrode 22b functions as a gate electrode of the MOSFET 20b. The electrode arranged on the lower portion of the MOSFET 20b functions as a drain electrode of the MOSFET 20b.

With the above arrangement, the MOSFETs 20a and 20b are arranged apart from each other in the X direction, for example.

The support base 30 is provided on the upper face of the substrate B. The support base 30 is arranged so as to be sandwiched, for example, in the Y direction between the electrode pads 10a and 10b and the electrode pads 70 and 71. The support base 30 has a plate-like shape extending in the X and Y directions. The support base 30 supports the light receiver 40 and the light emitter 60. The support base 30 may be, for example, a conductor or an insulator. The support base 30 may be made, for example, of a composite material of a conductor and an insulator. From the viewpoint of reducing the coupling capacitance with the MOSFETs 20a and 20b, it is preferable that the support base 30 be an insulator.

The light receiver 40 is provided in contact with an upper face of the support base 30. The light receiver 40 is arranged, for example, such that the light receiver 40 has a light-receiving surface on an upper face thereof.

The light receiver 40 includes electrodes 41, 42, 43 and 44. The electrodes 41 to 44 are arranged on the upper face of the light receiver 40. The electrodes 41 and 43 function as first and second cathode electrodes of the light receiver 40, respectively. The electrodes 42 and 44 function as first and second anode electrodes of the light receiver 40, respectively. That is, the electrodes 41 and 43 are electrically coupled within the light receiver 40. The electrodes 42 and 44 are electrically coupled within the light receiver 40.

The light emitter 60 is provided above the light receiver 40. The light emitter 60 is arranged such that it has a light emitting surface on a lower face thereof. The light emitting surface of the light emitter 60 faces the light-receiving surface of the light receiver 40.

The light emitter 60 includes electrodes 61 and 62. The electrodes 61 and 62 are arranged on an upper face of the light emitter 60. The electrode 61 functions as an anode electrode of the light emitter 60. The electrode 62 functions, for example, as a cathode electrode of the light emitter 60.

Between the light emitter 60 and the light receiver 40, an adhesive layer 50 is provided in contact with both the light emitter 60 and the light receiver 40. The adhesive layer 50 is made, for example, of an insulating material that is transparent to the light emitted from the light emitter 60.

The ferrite bead FB1 is a filter having, for example, a rectangular prism shape and a function of improving the high frequency characteristics of a signal passing therethrough. The ferrite bead FB1 includes, for example, electrodes FP11 and FP12. The electrode FP11 is provided at a first end of the ferrite bead FB1. The electrode FP12 is provided at a second end of the ferrite bead FB1. The ferrite bead FB1 is arranged to bridge between the light receiver 40 and the MOSFET 20a. Specifically, at the first end of the ferrite bead FB1, the electrode FP11 is in contact with the electrode 41 of the light receiver 40 via a conductive paste or the like. At the second end of the ferrite bead FB1, the electrode FP12 is in contact with the electrode 21a of the MOSFET 20a via a conductive paste or the like. Thus, the ferrite bead FB1 electrically couples the electrode 41 and the electrode 21a to each other.

The ferrite bead FB2 is a filter having, for example, a rectangular prism shape and a function of improving the high frequency characteristics of a signal passing therethrough. The ferrite bead FB2 includes, for example, electrodes FP21 and FP22. The electrode FP21 is provided at a first end of the ferrite bead FB2. The electrode FP22 is provided at a second end of the ferrite bead FB2. The ferrite bead FB2 is arranged to bridge between the light receiver 40 and the MOSFET 20b. Specifically, at the first end of the ferrite bead FB2, the electrode FP21 is in contact with the electrode 43 of the light receiver 40 via a conductive paste or the like. At the second end of the ferrite bead FB2, the electrode FP22 is in contact with the electrode 21b of the MOSFET 20b via a conductive paste or the like. Thus, the ferrite bead FB2 electrically couples the electrode 43 and the electrode 21b to each other.

With the above arrangement, the ferrite beads FB1 and FB2 are arranged apart from each other in the X direction. From the perspective of ease of implementation, it is preferable that each of the ferrite beads FB1 and FB2 be provided horizontally with respect to the substrate B. Thus, it is preferable that the upper face of the light receiver 40 and the upper face of each of the MOSFETs 20a and 20b be at the same position in the Z direction. In other words, it is preferable that the height of the upper face of the light receiver 40 from the substrate B be approximately equal to the height of the upper face of each of the MOSFETs 20a and 20b from the substrate B.

The electrodes 80, 81, 82a and 82b are arranged such that they are in contact with the lower face of the substrate B, for example.

A signal is transmitted between the electrodes 80 and 81, for example, by equipment and circuits not shown. Although not shown in FIG. 2, the electrode 80 is electrically coupled to the electrode pad 70, for example, through a conductor (a via) that penetrates the substrate B. Although not shown in FIG. 2, the electrode 81, like the electrode 80, is electrically coupled to the electrode pad 71, for example, through a conductor (a via) that penetrates the substrate B.

The electrodes 82a and 82b are each coupled to a circuit or the like provided outside the semiconductor device 1. Although not shown in FIG. 2, the electrode 82a is electrically coupled to an electrode arranged on the lower portion of the MOSFET 20a, for example, through a conductor (a via) penetrating the substrate B, an electrode pad 10a and a conductive paste. Although not shown in FIG. 2, the electrode 82b, like the electrode 82a, is electrically coupled to an electrode arranged on the lower portion of the MOSFET 20b, for example, through a conductor (a via) penetrating the substrate B, an electrode pad 10b and a conductive paste.

The sealing material S is provided in such a manner as to cover the MOSFETs 20a and 20b, the support base 30, the light receiver 40, the light emitter 60, the ferrite beads FB1 and FB2, and the electrode pads 10a, 10b, 70 and 71. The sealing material S may contain, for example, a non-transparent material.

In the configuration of the semiconductor device 1 described above, the electrode pads 10a and 70, the MOSFET 20a, and the ferrite bead FB1 may be arranged symmetrically to the electrode pads 10b and 71, the MOSFET 20b, and the ferrite bead FB2, with respect to the YZ plane, for example.

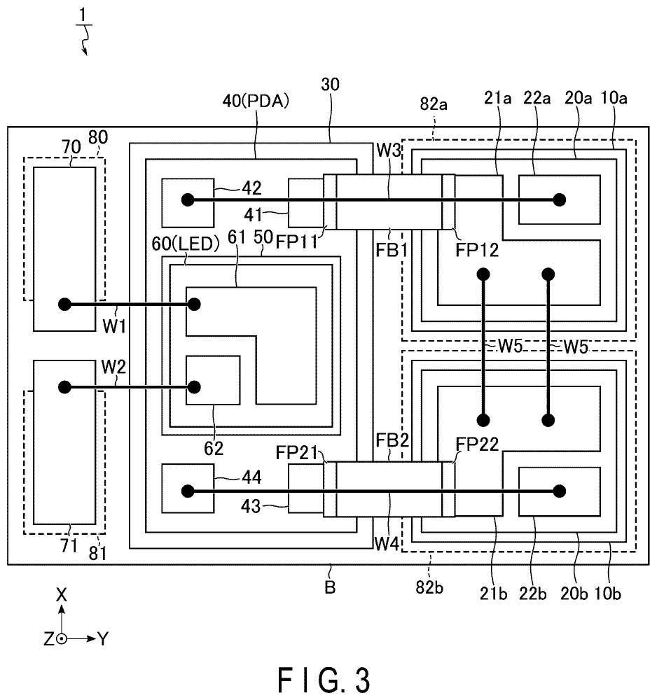

Next, the internal wiring of the semiconductor device 1 will be described with reference to FIG. 3. FIG. 3 is a plan view showing an example of the planar structure of the semiconductor device according to the first embodiment.

The semiconductor device 1 further includes wires W1, W2, W3, W4 and W5. The wires W1 to W5 are covered with the sealing material S together with the MOSFETs 20a and 20b, the support base 30, the light receiver 40, the light emitter 60, the ferrite beads FB1 and FB2, and the electrode pads 10a, 10b, 70 and 71.

The wires W1 to W5 are conductors made of a conductive material. Specifically, the wires W1 to W5 are wires (bonding wires) formed by wire bonding.

The wire W1 electrically couples the electrode pad 70 and the electrode 61 to each other. The wire W2 electrically couples the electrode pad 71 and the electrode 62 to each other. The wire W3 electrically couples the electrode 42 and the electrode 22a to each other. The wire W4 electrically couples the electrode 44 and the electrode 22b to each other. The wires W5 electrically couple the electrode 21a and the electrode 21b to each other. In the example in FIG. 3, the electrodes 21a and 21b are shown as being coupled by two wires W5, but this is not restrictive. The number of wires W5 used for coupling the electrodes 21a and 21b may be one or three or more.

In the above configuration, the wires W1 and W2 are arranged, for example, to extend in the Y direction in plan view and to have the same wiring length. The wires W3 and W4 are arranged, for example, to extend in the Y direction in plan view without contacting the ferrite beads FB1 and FB2, respectively, and to have the same wiring length. The two wires W5 are arranged, for example, to extend in the X direction in plan view and to have the same wiring length. The wires W1 and W3 and the wires W2 and W4 can be arranged symmetrically with respect to the YZ plane, for example.

The electrode 41 and the electrode 21a are electrically coupled by the ferrite bead FB1 without using any wire. The electrode 43 and the electrode 21b are electrically coupled by the ferrite bead FB2 without using any wire.

According to the first embodiment, the ferrite beads FB1 and FB2 are arranged inside the package of the semiconductor device 1 sealed with the sealing material S. This enables the suppression of noise generation in signals between MOSFETs 20a and 20b without mounting ferrite beads outside the package of the semiconductor device 1. Therefore, the transmission characteristics of signals between the MOSFETs 20a and 20b can be improved and an increase in the mounting area outside the package can be reduced.

Additionally, in a case where a first signal flows between the sources of two MOSFETs and a second signal flows in a direction intersecting the first signal inside or near a photorelay device, there is a possibility that noise will be generated in the first signal due to interaction with the second signal. Such noise occurs, for example, in a high-frequency band around 3 GHZ and can therefore become an unignorable factor in degrading the transmission characteristics of the photorelay device.

According to the first embodiment, the semiconductor device 1 includes ferrite beads FB1 and FB2 inside the package. This eliminates the need to mount a filter outside the package, thereby enabling suppression of an increase in the external mounting area of the package.

In addition, the ferrite bead FB1 is provided between the first cathode electrode of the light receiver 40 and the source electrode of the MOSFET 20a. The ferrite bead FB2 is provided between the second cathode electrode of the light receiver 40 and the source electrode of the MOSFET 20b. This allows the unnecessary stub length to be short as compared to a case where a filter is mounted outside the package.

The ferrite bead FB1 electrically couples the first cathode electrode of the light receiver 40 and the source electrode of the MOSFET 20a without using wires. The ferrite bead FB2 electrically couples the second cathode electrode of the light receiver 40 and the source electrode of the MOSFET 20b without using wires. This allows the unnecessary stub to be reduced to a negligible level. Therefore, the transmission characteristics in the high frequency band can be improved. In addition, the number of wires used for coupling the light receiver 40 and the MOSFETs 20a and 20b can be reduced and the manufacturing cost of the semiconductor device 1 can be reduced thereby.

The light receiver 40 and the MOSFETs 20a and 20b are arranged such that their upper faces are at the same position in the Z direction. Therefore, electrodes FP11 and FB12 of the ferrite bead FB1 can be easily mounted on the upper face of the electrode 41 and the upper face of the electrode 21a, respectively. Likewise, electrodes FP21 and FB22 of the ferrite bead FB2 can be easily mounted on the upper face of the electrode 43 and the upper face of the electrode 21b, respectively. Accordingly, an increase in the manufacturing load of the semiconductor device 1 can be suppressed.

### 2. Second Embodiment

Next, a description will be given of a semiconductor memory device according to the second embodiment. In the following, a description will be given mainly of the configurations differentiating the second embodiment from the first embodiment. As for the configurations similar to those of the first embodiment, a description of them will be omitted.

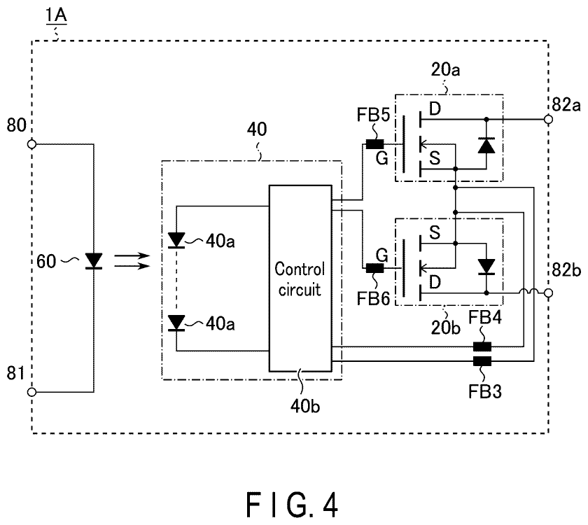

FIG. 4 is a circuit diagram showing an example of a circuit configuration of a semiconductor device according to the second embodiment. FIG. 4 corresponds to FIG. 1 referred to in connection with the first embodiment.

In addition to the electrodes 80, 81, 82a and 82b, the MOSFETs 20a and 20b, the light receiver 40, and the light emitter 60, the semiconductor device 1A further includes ferrite beads FB3, FB4, FB5 and FB6.

The gate of the MOSFET 20a is coupled to the first anode electrode of the light receiver 40 via the ferrite bead FB5. The gate of the MOSFET 20b is coupled to the second anode electrode of the light receiver 40 via the ferrite bead FB6. The source of the MOSFET 20a is coupled to the first cathode electrode of the light receiver 40 via the ferrite bead FB3. The source of the MOSFET 20b is coupled to the second cathode electrode of the light receiver 40 via the ferrite bead FB4. The drain of the MOSFET 20a is coupled to the electrode 82a. The drain of the MOSFET 20b is coupled to the electrode 82b.

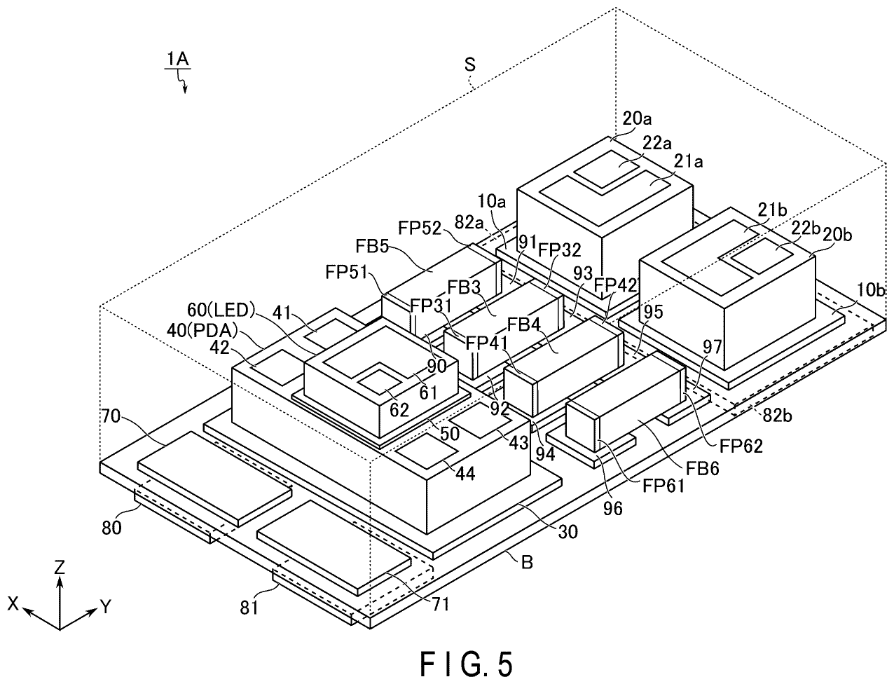

Next, the structure of the semiconductor device 1A will be described with reference to FIG. 5. FIG. 5 is a perspective view showing an example of a structure of the semiconductor device according to the second embodiment. FIG. 5 corresponds to FIG. 2 referred to in connection with the first embodiment.

In addition to the substrate B, the electrode pads 10a, 10b, 70 and 71, the support base 30, the adhesive layer 50 and the sealing material S, the semiconductor device 1A further includes pads 90, 91, 92, 93, 94, 95, 96 and 97.

The pads 90, 91, 92, 93, 94, 95, 96 and 97 are component-mounting pads provided on the upper face of the substrate B and located between the support base 30 and the electrode pads 10a and 10b. The pads 90, 91, 92, 93, 94, 95, 96 and 97 are conductive pads made, for example, of metal foils containing copper. The pads 90 and 91 are arranged apart from each other in the Y direction. The pads 92 and 93 are arranged apart from each other in the Y direction. The pads 94 and 95 are arranged apart from each other in the Y direction. The pads 96 and 97 are arranged apart from each other in the Y direction. The pads 90, 92, 94 and 96 are arranged apart from each other in the X direction in this order. The pads 91, 93, 95 and 97 are arranged apart from each other in the X direction in this order.

The ferrite bead FB3 is a filter having, for example, a rectangular prism shape and a function of improving the high frequency characteristics of a signal passing therethrough. The ferrite bead FB3 includes, for example, electrodes FP31 and FP32. The electrode FP31 is provided at a first end of the ferrite bead FB3. The electrode FP32 is provided at a second end of the ferrite bead FB3. The ferrite bead FB3 is arranged so as to bridge between the pad 92 and the pad 93. Specifically, at the first end of the ferrite bead FB3, the electrode FP31 is in contact with the pad 92 via a conductive paste or the like. At the second end of the ferrite bead FB3, the electrode FP32 is in contact with the pad 93 via a conductive paste or the like. Thus, the ferrite bead FB3 electrically couples the pad 92 and the pad 93 to each other.

The ferrite bead FB4 is a filter having, for example, a rectangular prism shape and a function of improving the high frequency characteristics of a signal passing therethrough. The ferrite bead FB4 includes, for example, electrodes FP41 and FP42. The electrode FP41 is provided at a first end of the ferrite bead FB4. The electrode FP42 is provided at a second end of the ferrite bead FB4. The ferrite bead FB4 is arranged so as to bridge between the pad 94 and the pad 95. Specifically, at the first end of the ferrite bead FB4, the electrode FP41 is in contact with the pad 94 via a conductive paste or the like. At the second end of the ferrite bead FB4, the electrode FP42 is in contact with the pad 95 via a conductive paste or the like. Thus, the ferrite bead FB4 electrically couples the pad 94 and the pad 95 to each other.

The ferrite bead FB5 is a filter having, for example, a rectangular prism shape and a function of improving the high frequency characteristics of a signal passing therethrough. The ferrite bead FB5 includes, for example, electrodes FP51 and FP52. The electrode FP51 is provided at a first end of the ferrite bead FB5. The electrode FP52 is provided at a second end of the ferrite bead FB5. The ferrite bead FB5 is arranged so as to bridge between the pad 90 and the pad 91. Specifically, at the first end of the ferrite bead FB5, the electrode FP51 is in contact with the pad 90 via a conductive paste or the like. At the second end of the ferrite bead FB5, the electrode FP52 is in contact with the pad 91 via a conductive paste or the like. Thus, the ferrite bead FB5 electrically couples the pad 90 and the pad 91 to each other.

The ferrite bead FB6 is a filter having, for example, a rectangular prism shape and a function of improving the high frequency characteristics of a signal passing therethrough. The ferrite bead FB6 includes, for example, electrodes FP61 and FP62. The electrode FP61 is provided at a first end of the ferrite bead FB6. The electrode FP62 is provided at a second end of the ferrite bead FB6. The ferrite bead FB6 is arranged so as to bridge between the pad 96 and the pad 97. Specifically, at the first end of the ferrite bead FB6, the electrode FP61 is in contact with the pad 96 via a conductive paste or the like. At the second end of the ferrite bead FB6, the electrode FP62 is in contact with the pad 97 via a conductive paste or the like. Thus, the ferrite bead FB6 electrically couples the pad 96 and the pad 97 to each other.

With the above arrangement, the ferrite beads FB3, FB4, FB5 and FB6 are arranged apart from each other in the X direction.

The sealing material S is provided in such a manner as to cover the MOSFETs 20a and 20b, the support base 30, the light receiver 40, the light emitter 60, the ferrite beads FB3, FB4, FB5 and FB6, the electrode pads 10a, 10b, 70 and 71, and the pads 90, 91, 92, 93, 94, 95, 96 and 97.

In the configuration of the semiconductor device 1A described above, the electrode pads 10a and 70, the MOSFET 20a and the ferrite beads FB3 and FB5 can be arranged symmetrically to the electrode pads 10b and 71, the MOSFET 20b, and the ferrite beads FB4 and FB6, with respect to the YZ plane, for example.

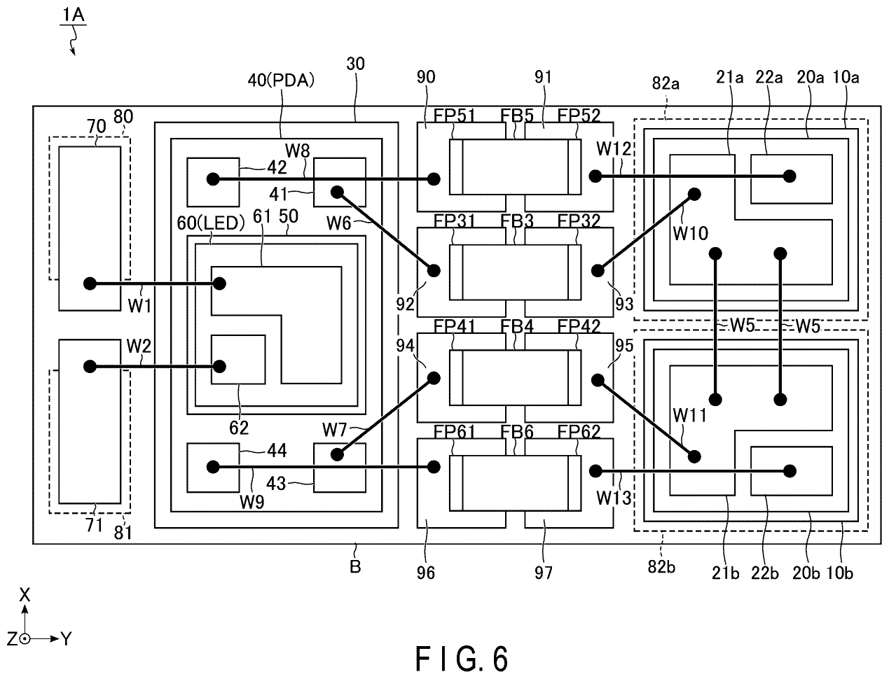

Next, the internal wiring of the semiconductor device 1A will be described with reference to FIG. 6. FIG. 6 is a plan view showing an example of the planar structure of the semiconductor device according to the second embodiment. FIG. 6 corresponds to FIG. 3 referred to in connection with the first embodiment.

The semiconductor device 1A further includes wires W6, W7, W8, W9, W10, W11, W12 and W13, in addition to the wires W1, W2 and W5. The wires W1, W2 and W5 to W13 are covered with a sealing material S together with the MOSFETs 20a and 20b, the support base 30, the light receiver 40, the light emitter 60, the ferrite beads FB3 to FB6, the electrode pads 10a, 10b, 70 and 71, and the pads 90 to 97.

The wires W1, W2 and W5 to W13 are conductors made of a conductive material. Specifically, the wires W1, W2 and W5 to W13 are, for example, wires (bonding wires) formed by wire bonding.

The wire W6 electrically couples the electrode 41 and pad 92 to each other. The wire W7 electrically couples the electrode 43 and pad 94 to each other. The wire W8 electrically couples the electrode 42 and pad 90 to each other. The wire W9 electrically couples the electrode 44 and pad 96 to each other. The wire W10 electrically couples the pad 93 and the electrode 21a to each other. The wire W11 electrically couples the pad 95 and the electrode 21b to each other. The wire W12 electrically couples the pad 91 and the electrode 22a to each other. The wire W13 electrically couples the pad 97 and the electrode 22b to each other.

In the above configuration, the wires W6 and W7 are arranged to have, for example, the same wiring length. The wires W8 and W9 are arranged, for example, to extend in the Y direction in plan view and to have the same wiring length. The wires W10 and W11 are arranged, for example, to have the same wiring length. The wires W12 and W13 are arranged, for example, to extend in the Y direction in plan view and to have the same wiring length. The wires W1, W6, W8, W10 and W12 and the wires W2, W7, W9, W11 and W13 can be arranged symmetrically with respect to the YZ plane, for example.

It should be noted that the pads 90 and 91 are electrically coupled by the ferrite bead FB5 without using any wire. The pads 92 and 93 are electrically coupled by the ferrite bead FB3 without using any wire. The pads 94 and 95 are electrically coupled by the ferrite bead FB4 without using any wire. The pads 96 and 97 are electrically coupled by the ferrite bead FB6 without using any wire.

According to the second embodiment, the semiconductor device 1A includes the ferrite beads FB3, FB4, FB5 and FB6 inside the package. This eliminates the need to mount a filter outside the package, thereby enabling suppression of an increase in the external mounting area of the package.

In addition, the ferrite bead FB3 is provided between the first cathode electrode of the light receiver 40 and the source electrode of the MOSFET 20a. The ferrite bead FB4 is provided between the second cathode electrode of the light receiver 40 and the source electrode of the MOSFET 20b. This allows the unnecessary stub length to be short as compared to a case where a filter is mounted outside the package.

In addition, the ferrite bead FB5 is provided between the first anode electrode of the light receiver 40 and the gate electrode of the MOSFET 20a. The ferrite bead FB6 is provided between the second anode electrode of the light receiver 40 and the gate electrode of the MOSFET 20b. This allows the stub length caused by not only the source signal but also the gate signal to be reduced. Therefore, the transmission characteristics are further improved.

The ferrite beads FB3, FB4, FB5, and FB6 are respectively provided on the upper faces of the pads: the FB3 on the pads 90 and 91, the FB4 on the pads 92 and 93, the FB5 on the pads 94 and 95, and the FB6 on the pads 96 and 97. Also, the pads 90, 91, 92, 93, 94, 95, 96 and 97 are provided between the support base 30 and the electrode pads 10a and 10b. This allows the manufacturing load to be reduced as compared to the case where the ferrite beads are provided to bridge the light receiver and the electrodes on the upper face of each MOSFET.

### 3. Others

In connection with the above-described second embodiment, a description was given of a case where the wires W6, W7, W8, W9, W10, W11, W12 and W13 are coupled to the pads 92, 94, 90, 96, 93, 95, 91 and 97, respectively, but this is not restrictive. For example, each of the wires W6, W7, W8, W9, W10, W11, W12 and W13 may be coupled directly to a ferrite bead.

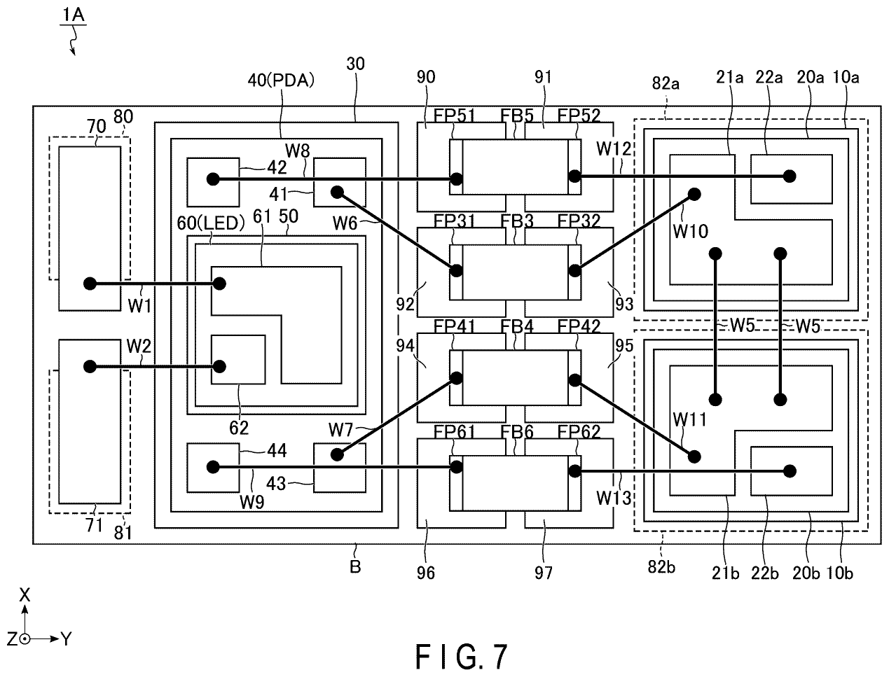

FIG. 7 is a plan view showing an example of a planar structure of a semiconductor device according to a first modification. FIG. 7 corresponds to FIG. 6 referred to in connection with the second embodiment.

As shown in FIG. 7, the wire W6 may be coupled to the electrode FP31 instead of the pad 92. The wire W7 may be coupled to the electrode FP41 instead of the pad 94. The wire W8 may be coupled to the electrode FP51 instead of the pad 90. The wire W9 may be coupled to the electrode FP61 instead of the pad 96. The wire W10 may be coupled to the electrode FP32 instead of the pad 93. The wire W11 may be coupled to the electrode FP42 instead of the pad 95. The wire W12 may be coupled to the electrode FP52 instead of the pad 91. The wire W13 may be coupled to the electrode FP62 instead of the pad 97.

In this case, the pads on which the ferrite beads FB3, FB4, FB5 and FB6 are mounted may be insulating pads instead of conductive pads. Thus, the coupling capacitance can be reduced between the pads that support the ferrite beads FB3, FB4, FB5 and FB6, and the electrode pads 10a and 10b.

In connection with the second embodiment described above, a description was given of the case where the two electrodes FP of each of the ferrite beads FB3, FB4, FB5 and FB6 are arranged to face each other in the Y direction, but this is not restrictive. For example, the two electrodes FP of each of the ferrite beads FB3, FB4, FB5 and FB6 may be arranged to face each other in the Z direction.

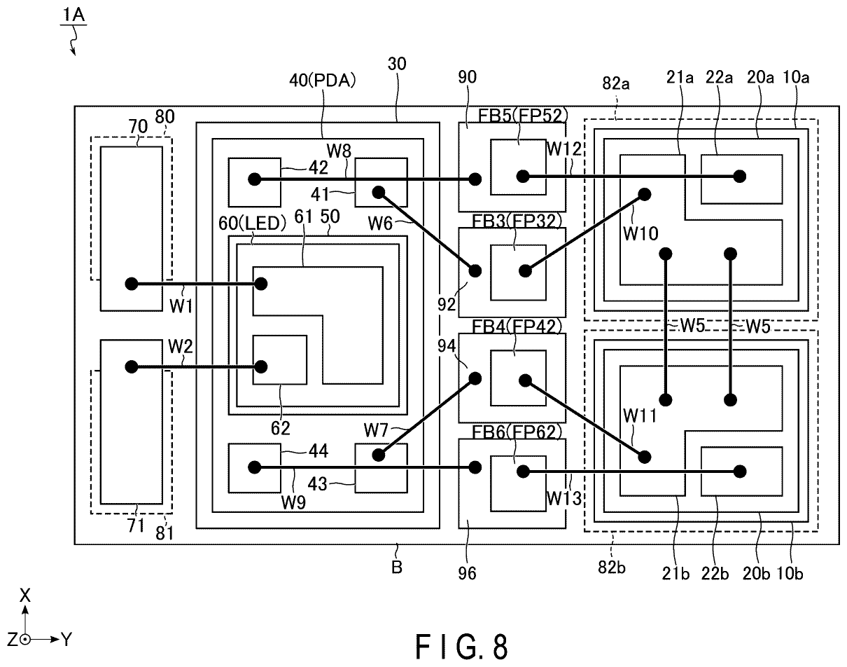

FIG. 8 is a plan view showing an example of the planar structure of a semiconductor device according to a second modification. FIG. 8 corresponds to FIG. 6 referred to in connection with the second embodiment.

As shown in FIG. 8, the ferrite bead FB3 may be provided on the upper face of the pad 92 such that it is in contact with the electrode FP31. The ferrite bead FB4 may be provided on the upper face of the pad 94 such that it is in contact with the electrode FP41. The ferrite bead FB5 may be provided on the upper face of the pad 90 such that it is in contact with the electrode FP51. The ferrite bead FB6 may be provided on the upper face of the pad 96 such that it is in contact with the electrode FP61.

In this case, the wire W10 may be coupled to the electrode FP32 without using an electrode on the substrate B. The wire W11 may be coupled to the electrode FP42 without using an electrode on the substrate B. The wire W12 may be coupled to the electrode FP52 without using an electrode on the substrate B. The wire W13 may be coupled to the electrode FP62 without using an electrode on the substrate B.

With the above configuration, the number of pads mounted on the substrate B can be reduced as compared to the case where two electrodes FP of one ferrite bead FB are arranged in contact with different metal pads. Thus, the length of the semiconductor device 1A in the Y direction can be reduced.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor and a second transistor whose source electrodes are electrically coupled to each other;
a light emitter;
a light receiver including a first cathode electrode and a second cathode electrode and configured to turn the first transistor and the second transistor on or off, depending on a light emission state of the light emitter;
a first filter electrically coupling the first cathode electrode of the light receiver and the source electrode of the first transistor; and
a second filter electrically coupling the second cathode electrode of the light receiver and the source electrode of the second transistor.

2. The semiconductor device according to claim 1, further comprising:
a substrate including a first face and a second face that are opposite to each other;
a support base provided on the first face of the substrate and in contact with a lower face of the light receiver;
a first pad provided on the first face of the substrate and in contact with a lower face of the first transistor; and
a second pad provided on the first face of the substrate and in contact with a lower face of the second transistor,
wherein the first filter includes a first end that is in contact with the first cathode electrode of the light receiver and a second end that is in contact with the source electrode of the first transistor, and
the second filter includes a first end that is in contact with the second cathode electrode of the light receiver and a second end that is in contact with the source electrode of the second transistor.

3. The semiconductor device according to claim 2, wherein
the first cathode electrode and the second cathode electrode of the light receiver are provided on an upper face of the light receiver,
the source electrode of the first transistor is provided on an upper face of the first transistor,
the source electrode of the second transistor is provided on an upper face of the second transistor, and
heights from the substrate to the upper face of the light receiver, the upper face of the first transistor, and the upper face of the second transistor are substantially equal.

4. The semiconductor device according to claim 2, wherein the support base is an insulator.

5. The semiconductor device according to claim 1, further comprising:
a substrate including a first face;
a support base provided on the first face of the substrate and in contact with a lower face of the light receiver;
a first pad provided on the first face of the substrate and in contact with a lower face of the first transistor;
a second pad provided on the first face of the substrate and in contact with a lower face of the second transistor;
a third pad provided on the first face of the substrate and located between the support base and the first pad; and
a fourth pad provided on the first face of the substrate and located between the support base and the second pad,
wherein the first filter includes a first end that is in contact with the third pad, and
the second filter includes a first end that is in contact with the fourth pad.

6. The semiconductor device according to claim 5, further comprising:
a fifth pad provided on the first face of the substrate and located between the third pad and the first pad; and
a sixth pad provided on the first face of the substrate and located between the fourth pad and the second pad,
wherein the first filter includes a second end that is in contact with the fifth pad, and
the second filter includes a second end that is in contact with the sixth pad.

7. The semiconductor device according to claim 6, further comprising:
a first wire electrically coupling the first cathode electrode of the light receiver and the third pad;
a second wire electrically coupling the second cathode electrode of the light receiver and the fourth pad;
a third wire electrically coupling the source electrode of the first transistor and the fifth pad; and
a fourth wire electrically coupling the source electrode of the second transistor and the sixth pad.

8. The semiconductor device according to claim 6, further comprising:
a first wire electrically coupling the first cathode electrode of the light receiver and the first end of the first filter;
a second wire electrically coupling the second cathode electrode of the light receiver and the first end of the second filter;
a third wire electrically coupling the source electrode of the first transistor and the second end of the first filter; and
a fourth wire electrically coupling the source electrode of the second transistor and the second end of the second filter.

9. The semiconductor device according to claim 6, wherein
the first pad and the second pad are aligned in a first direction,
a set of the first pad and the second pad and the support base are aligned in a second direction intersecting the first direction, and
the third pad and the fourth pad are aligned in the first direction.

10. The semiconductor device according to claim 9, wherein the fifth pad and the sixth pad are aligned in the first direction.

11. The semiconductor device according to claim 5, further comprising:
a first wire electrically coupling the first cathode electrode of the light receiver and the third pad;
a second wire electrically coupling the second cathode electrode of the light receiver and the fourth pad;
a third wire electrically coupling the source electrode of the first transistor and a second end of the first filter; and
a fourth wire electrically coupling the source electrode of the second transistor and a second end of the second filter.

12. The semiconductor device according to claim 9, wherein
the first pad and the second pad are aligned in a first direction,
a set of the first pad and the second pad and the support base are aligned in a second direction intersecting the first direction, and
the third pad and the fourth pad are aligned in the first direction.

13. The semiconductor device according to claim 12, wherein
the second end of the first filter is located above the first end of the first filter, and
the second end of the second filter is located above the first end of the second filter.

14. The semiconductor device according to claim 1, wherein the light receiver includes a first anode electrode and a second anode electrode,
the semiconductor device further comprising:
a third filter electrically coupling the first anode electrode of the light receiver and a gate electrode of the first transistor; and
a fourth filter electrically coupling the second anode electrode of the light receiver and a gate electrode of the second transistor.

15. The semiconductor device according to claim 14, further comprising:
a substrate including a first face;
a support base provided on the first face of the substrate and in contact with a lower face of the light receiver;
a first pad provided on the first face of the substrate and in contact with a lower face of the first transistor;
a second pad provided on the first face of the substrate and in contact with a lower face of the second transistor;
a third pad and a seventh pad provided on the first face of the substrate and located between the support base and the first pad; and
a fourth pad and an eighth pad provided on the first face of the substrate and located between the support base and the second pad,
wherein the first filter includes a first end that is in contact with the third pad,
the second filter includes a first end that is in contact with the fourth pad,
the third filter includes a first end that is in contact with the seventh pad, and
the fourth filter includes a first end that is in contact with the eighth pad.

16. The semiconductor device according to claim 15, wherein
the first pad and the second pad are aligned in a first direction,
a set of the first pad and the second pad and the support base are aligned in a second direction intersecting the first direction, and
the seventh pad, the third pad, the fourth pad, and the eighth pad are arranged in this order in the first direction.

17. The semiconductor device according to claim 16, wherein
a second end of the first filter is located above the first end of the first filter,
a second end of the second filter is located above the first end of the second filter,
a second end of the third filter is located above the first end of the third filter, and
a second end of the fourth filter is located above the first end of the fourth filter.

18. The semiconductor device according to claim 16, further comprising:
a fifth pad provided on the first face of the substrate and located between the third pad and the first pad;
a sixth pad provided on the first face of the substrate and located between the fourth pad and the second pad;
a ninth pad provided on the first face of the substrate and located between the seventh pad and the first pad; and
a tenth pad provided on the first face of the substrate and located between the eighth pad and the second pad,
wherein the first filter includes a second end that is in contact with the fifth pad,
the second filter includes a second end that is in contact with the sixth pad,
the third filter includes a second end that is in contact with the ninth pad, and
the fourth filter includes a second end that is in contact with the tenth pad.

19. The semiconductor device according to claim 18, further comprising:
a first wire electrically coupling the first cathode electrode of the light receiver and the third pad;
a second wire electrically coupling the second cathode electrode of the light receiver and the fourth pad;
a third wire electrically coupling the source electrode of the first transistor and the fifth pad;
a fourth wire electrically coupling the source electrode of the second transistor and the sixth pad;
a fifth wire electrically coupling the first anode electrode of the light receiver and the seventh pad;
a sixth wire electrically coupling the second anode electrode of the light receiver and the eighth pad;
a seventh wire electrically coupling the gate electrode of the first transistor and the ninth pad; and
an eighth wire electrically coupling the gate electrode of the second transistor and the tenth pad.

20. The semiconductor device according to claim 18, further comprising:
a first wire electrically coupling the first cathode electrode of the light receiver and the first end of the first filter;
a second wire electrically coupling the second cathode electrode of the light receiver and the first end of the second filter;
a third wire electrically coupling the source electrode of the first transistor and the second end of the first filter;
a fourth wire electrically coupling the source electrode of the second transistor and the second end of the second filter;
a fifth wire electrically coupling the first anode electrode of the light receiver and the first end of the third filter;
a sixth wire electrically coupling the second anode electrode of the light receiver and the first end of the fourth filter;
a seventh wire electrically coupling the gate electrode of the first transistor and the second end of the third filter; and
an eighth wire electrically coupling the gate electrode of the second transistor and the second end of the fourth filter.
